(19) United States
(12) Patent Application Publication
(10) Pub. No.: US 2019/0131353 A1
(43) Pub. Date: May 2, 2019

(54) TOUCH OLED DISPLAY PANEL AND DISPLAY DEVICE

(71) Applicant: Yuejun TANG, Wuhan, Hubei (CN)

(72) Inventor: Yuejun TANG, Wuhan, Hubei (CN)

(21) Appl. No.: 15/739,829

(22) PCT Filed: Dec. 13, 2017
(86) PCT No.: PCT/CN2017/116001

§ 371 Date: Dec. 26, 2017

(30) Foreign Application Priority Data
Oct. 31, 2017 (CN) 201711048638.2

(51) Int. Cl. H01L 27/32; H01L 27/12; H01L 51/52; G09G 3/3225; G06F 3/041

(52) U.S. Cl. CPC H01L 27/323; H01L 27/1218; G06F 3/0412; G09G 3/3225; H01L 51/5246

(57) ABSTRACT

The present disclosure discloses a touch OLED display panel, including a TFT array substrate and an package cover plate opposite to each other, and a conductive connector arranged between the TFT array substrate and the package cover plate, wherein the TFT array substrate is provided with a chip bonding portion and a first connection terminal electrically connected to each other, a side of the package cover plate facing the TFT array substrate is provided with a touch electrode layer and a second connection terminal electrically connected to each other, the conductive connector electrically connects the first connection terminal and the second connection terminal to each other. The present disclosure further discloses a display device including the above-mentioned touch OLED display panel.

### RELATED APPLICATIONS

The present application is a National Phase of International Application Number PCT/CN2017/116001, filed Dec. 13, 2017, and claims the priority of China Application No. 201711048638.2, filed Oct. 31, 2017.

### FIELD OF THE DISCLOSURE

The present disclosure relates to a display technology field, and more particularly to a touch OLED display panel and a display device.

### BACKGROUND OF THE DISCLOSURE

With the development of the information age and the accelerating pace of life, touch technology has gradually replaced the traditional mouse and keyboard because of its user-friendly design and simple and quick input. It has been widely applied to a wide range of electronic products. Wherein the capacitive touch screen due to its advantages of fast response, high sensitivity, high reliability and durability are widely used.

OLED (Organic Light Emitting Diode) display device has self-luminous, wide viewing angle, high luminous efficiency, low power consumption, fast response time, low temperature characteristics, simply manufacturing process, low cost and other characteristics. At present, the touch OLED display device generally adopts separating the OLED display panel and the touch screen to form, and then bonds the two together (i.e. the add on mode). This touch OLED display device has the disadvantages of reducing light transmittance and thick.

### SUMMARY OF THE DISCLOSURE

In view of the deficiencies of the prior art, the present disclosure provides a touch OLED display panel. The touch structure is embedded in the OLED display panel and has the advantages of simple structure, thin thickness and high light transmittance.

In order to achieve the above object, the present disclosure adopts the following technical solutions:

a touch OLED display panel, including a TFT array substrate and an package cover plate opposite to each other, and a conductive connector arranged between the TFT array substrate and the package cover plate, wherein the TFT array substrate is provided with a chip bonding portion and a first connection terminal electrically connected to each other, a side of the package cover plate facing the TFT array substrate is provided with a touch electrode layer and a second connection terminal electrically connected to each other, the conductive connector electrically connects the first connection terminal and the second connection terminal to each other.

Wherein an organic light emitting structure layer is arranged on the TFT array substrate, a sealant frame is arranged between the TFT array substrate and the package cover plate, wherein the sealant frame surrounds the periphery of the organic light emitting structure layer, the chip bonding portion, the first connection terminal, the second connection terminal and the conductive connector are all located outside the sealant frame, and the touch electrode layer is located inside the sealant frame.

Wherein the chip bonding portion and the first connection terminal are arranged on a first side outside the sealant frame, and the second connection terminal is located on the first connection terminal.

Wherein a notch is formed on an area of the package cover plate corresponding to the first side, and the second connection terminal is arranged on a projection of both sides of the notch.

Wherein the chip bonding portion is arranged on the first side outside the sealant frame, the first connection terminal is arranged on a second side that is different from the first side and outside the sealant frame, the second connection terminal is located on the first connection terminal, and a connection trace between the first connection terminal and the chip bonding portion is arranged at an edge area of the TFT array substrate.

Wherein a notch is formed on an area of the package cover plate corresponding to the second side, and the second connection terminal is arranged on a projection of both sides of the notch.

Wherein the organic light emitting structure layer includes an anode layer, a luminescent material layer and a cathode layer arranged on the TFT array substrate sequentially.

Wherein the conductive connector is an anisotropic conductive adhesive.

Wherein a support member is further arranged at a position adjacent to the conductive connector and between the TFT array substrate and package cover plate.

The present disclosure further provides a display device, including a driving unit and a touch OLED display panel, wherein the driving unit provides a driving signal to the touch OLED display panel.

The touch OLED display panel and the display device of the present disclosure provided is embedded the touch structure into the OLED display panel. Specifically, the touch structure is arranged on the side of the package cover plate facing the TFT array substrate, which has the advantages of simple structure, thin thickness and high light transmittance. In addition, a conductive connector is arranged on the non-display area of the display panel, the connecting terminal of the touch structure is electrically connected to the TFT array substrate, and the display driver and the touch driver share the same chip bonding portion. It is not only reducing the complexity of the bonding process but also reducing the cost.

### BRIEF DESCRIPTION OF THE DRAWINGS

FIG. 1 is a schematic structural diagram of a touch OLED display panel provided in Embodiment 1 of the present disclosure;

FIG. 2 is a schematic plan view of a touch OLED display panel in Embodiment 1 of the present disclosure;

FIG. 3 is a schematic plan view of a touch OLED display panel of another specific embodiment in Embodiment 1 of the present disclosure:

FIG. 4 is a schematic structural diagram of a touch OLED display panel provided in Embodiment 2 of the present disclosure;

FIG. 5 is a schematic plan view of a touch OLED display panel in Embodiment 2 of the present disclosure:

FIG. 6 is a schematic plan view of a touch OLED display panel of another specific embodiment in Embodiment 2 of the present disclosure.

FIG. 7 is a schematic structural diagram of a touch OLED display panel of another specific embodiment in Embodiment 2 of the present disclosure;

FIG. 8 is a schematic structural diagram of a display device provided in Embodiment 3 of the present disclosure.

### DETAILED DESCRIPTION OF PREFERRED EMBODIMENTS

To make the objectives, technical solutions, and advantages of the present disclosure clearer, the following describes the specific implementation manners of the present disclosure in detail with reference to the accompanying drawings. Examples of these preferred embodiments are illustrated in the drawings. The embodiments of the present disclosure shown in the drawings and described in the drawings are merely exemplary and the present disclosure is not limited to these embodiments.

Here, it should also be noted that, in order to avoid obscuring the present disclosure with unnecessary detail, only the structures and/or processing steps that are closely related to the solution according to the present disclosure are shown in the drawings, other details that are less concern to the present disclosure are omitted.

### Embodiment 1

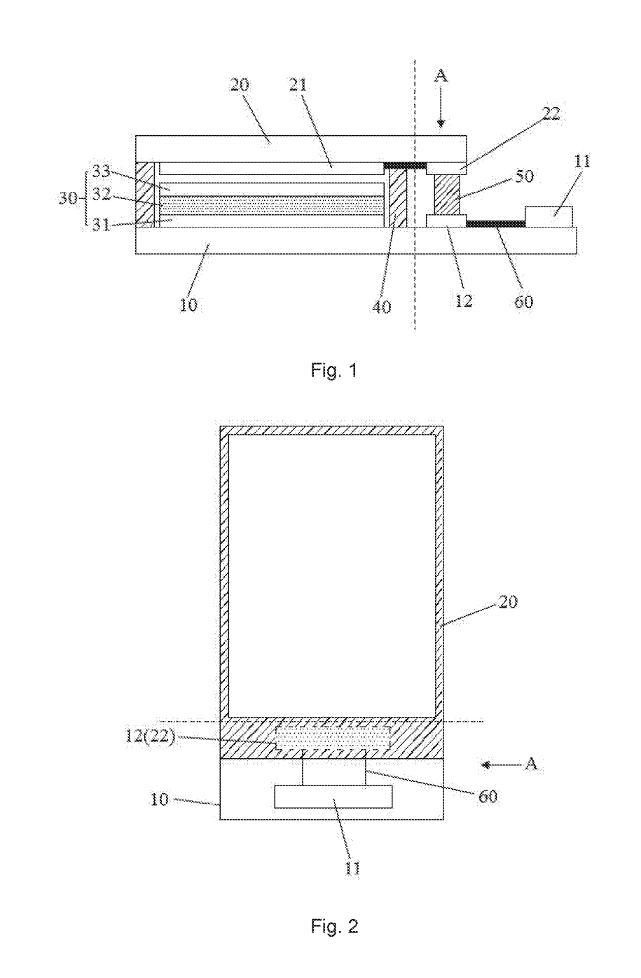

The present embodiment provides a touch OLED display panel, as shown in FIG. 1, the touch OLED display panel includes a TFT array substrate 10 and a package cover plate 20 opposite to each other, an organic light emitting structure layer 30 and a sealant frame 40 arranged between the array substrate 10 and the package cover plate 20, wherein the sealant frame 40 surrounds the periphery of the organic light emitting structure layer 30, the sealant frame 40 is an encapsulant. Specifically, the TFT array substrate 10, the package cover plate 20 and the sealant frame 40 are jointly surrounded to form a sealed cavity, and the organic light emitting structure layer 30 is arranged in the sealed cavity. Wherein an anode layer 31, a luminescent material layer 32 and a cathode layer 33 are arranged on the organic light emitting structure layer 30 sequentially.

Wherein the TFT array substrate 10 is provided with a chip bonding portion 11 and a first connection terminal 12 electrically connected to each other, wherein a side of the package cover plate 20 facing the TFT array substrate 10 is provided with a touch electrode layer 21 and a second connection terminal 22 electrically connected to each other. The TFT array substrate 10 is further provided with a conductive connector 50 arranged between the TFT array substrate 10 and the package cover plate 20, wherein the conductive connector 50 electrically connects the first connection terminal 12 and the second connection terminal 22 to each other. Specifically, the chip bonding portion 11, the first connection terminal 12, the second connection terminal 22 and the conductive connector 50 are all located outside the sealant frame 40, and the touch electrode layer 21 is located inside the sealant frame 40.

In the present embodiment, the conductive connector 50 is an anisotropic conductive adhesive.

In the present embodiment, referring to FIG. 1 and FIG. 2, on the TFT array substrate 10, the chip bonding portion 11 and the first connection terminal 12 are arranged on a first side A outside the sealant frame 40 respectively, the chip bonding portion 11 and the first connection terminal 12 are electrically connected to each other by a connection trace 60. On the package cover plate 20, the second connection terminal 22 is located on the first connection terminal 12, and is also arranged on the first side A outside the sealant frame 40. It should be noted that, in FIG. 2, the positions of the first connection terminal 12 and the second connection terminal 22 on the view are coincident.

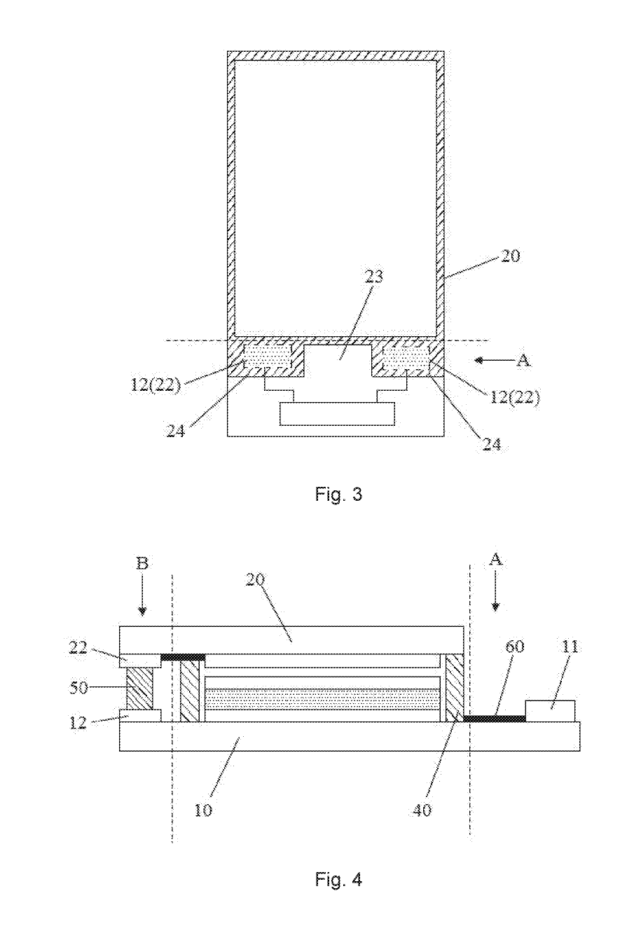

For a specific arrangement of the first connection terminal 12 and the second connection terminal 22, in another specific embodiment, as shown in FIG. 3, a notch 23 is formed on an area of the package cover plate 20 corresponding to the first side A, wherein the second connection terminal 22 is arranged on a projection 24 of both sides of the notch 23. At this time, the first connection terminal 12 is under the second connection terminal 22, and in FIG. 3, the positions of the first connection terminal 12 and the second connection terminal 22 coincide with each other in the view. When the touch OLED display panel is applied to some specific display devices, for example, a smart phone, the position of the notch 23 may provide a space for accommodating some electronic devices (such as cameras, horns and the like).

Wherein a display driving circuit (not shown) is further arranged on the TFT array substrate 10, the display driving circuit mainly includes signal traces of thin film transistor, data line and gate line arranged in an array. A base substrate of the TFT array substrate 10 may be a rigid substrate, such as a glass substrate, or may be a flexible substrate, for example, a flexible substrate formed of a polymer material such as polyimide (PI), polycarbonate (PC), Polyethersulfone (PES), polyethylene terephthalate (PET), polyethylene naphthalate (PEN), polyarylate (PAR) or glass fiber reinforced plastic (FRP).

Wherein the touch electrode layer 21 includes a touch electrode and a touch driving trace. The touch electrode is electrically connected to the second connection terminal 22 through the touch driving trace. Further, for the touch mode and the category, the touch electrode layer 21 may be touch electrode structures adopting self-capacitance or touch electrode structures adopting mutual capacitance, and the corresponding electrodes and their driving traces are electrically connected to the chip bonding portion 11 using the solution of the embodiment of the present disclosure. In addition, in the arrangement of the structure layer, the touch electrode layer 21 may be a single-layer touch electrode structure or a multi-layer touch electrode structure.

According to the touch OLED display panel of the above embodiment provided, the touch structure is embedded in the OLED display panel. Specifically, the touch structure is arranged on the side of the package cover plate facing the TFT array substrate, which has the advantages of simple structure, thin thickness and high light transmittance. In addition, a conductive connector is arranged on a non-display area of the display panel, the connection terminal of the touch structure is electrically connected to the TFT array substrate, and the display driver and the touch driver share the same chip bonding portion. It is not only reducing the complexity of the bonding process but also reducing the cost. Further, the display driver and the touch driver may also share the same driving chip, that is, touch and display driver integration (TDDI).

### Embodiment 2

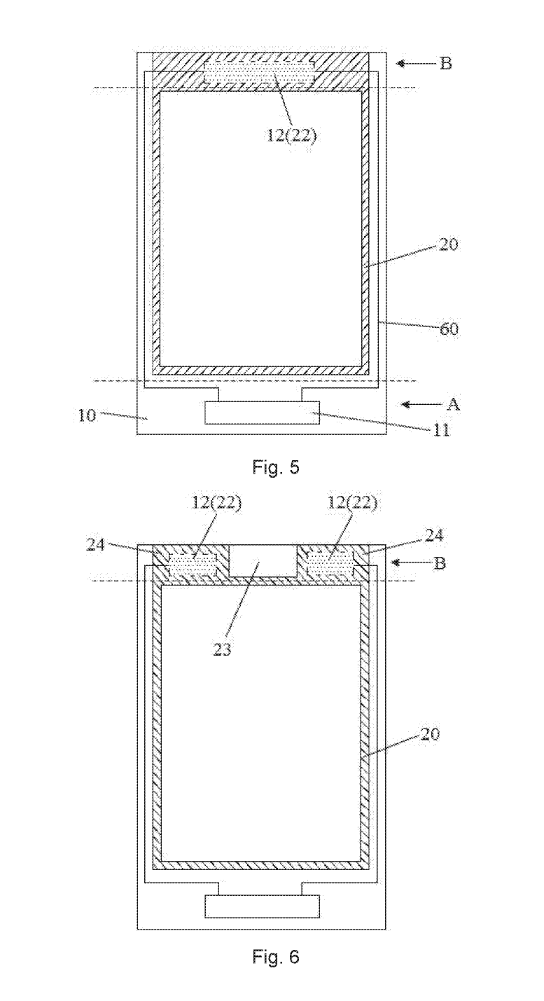

The present embodiment provides a touch OLED display panel. Different from Embodiment 1, referring to FIG. 4 and FIG. 5, on the TFT array substrate 10, the chip bonding portion 11 is arranged on a first side A outside the sealant frame 40, the first connection terminal 12 is arranged on a second side that is different from the first side A and outside the sealant frame 40, the connection trace 60 between the first connection terminal 12 and the chip bonding portion 11 is arranged at an edge area of the TFT array substrate 10. On the package cover plate 20, the second connection terminal 22 is on the first connection terminal 12, and is also a second side B arranged outside the sealant frame 40. It should be noted that, in FIG. 5, the positions of the first connection terminal 12 and the second connection terminal 22 on the view are coincident.

In the present embodiment, the first connection terminal 12, the second connection terminal 22 and the conductive connector 50 are arranged on a side different from the chip bonding portion 11, mainly for better utilizing the frame area of the display panel space. Wherein, the conductive connector 50 adopts an anisotropic conductive adhesive.

Further, similar in Embodiment 1, for a specific arrangement of the first connection terminal 12 and the second connection terminal 22, in another specific embodiment of the present embodiment, as shown in FIG. 6, a notch 23 is formed on an area of the package cover plate 20 corresponding to the second side B, the second connection terminal 22 is arranged on a projection 24 of both sides of the notch 23. At this time, the first connection terminal 12 is under the second connection terminal 22, in the FIG. 6, the positions of the first connection terminal 12 and the second connection terminal 22 coincide with each other in the view. When the touch OLED display panel is applied to some specific display devices, for example, a smart phone, the position of the notch 23 may provide a space for accommodating some electronic devices (such as cameras, horns and the like).

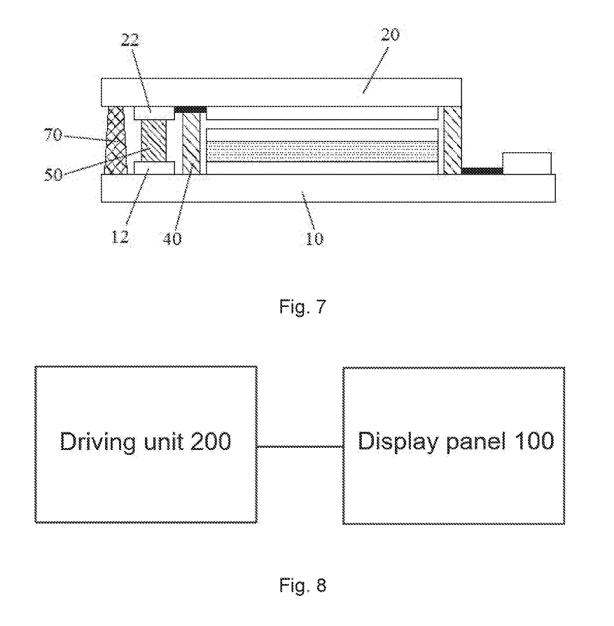

Further, in another specific embodiment of the present embodiment, as shown in FIG. 7, a support member 70 is further arranged at a position adjacent to the conductive connector 50 and between the TFT array substrate 10 and package cover plate 20. The support member 70 may be arranged on the side of the conductive connector 50 away from the sealant frame 40 (as shown in FIG. 7), may also be arranged between the conductive connector 50 and the sealant frame 40. In the present embodiment, the portion of the TFT array substrate 10 in which the first connection terminal 12 is arranged may be a material having a bending property. As a result, a better electrical connection between the conductive connector 50 and the first connection terminal 12 and the second connection terminal 22 can be achieved. The support member 70 serves to provide supporting force for maintaining a proper height between the TFT array substrate 10 and the package cover plate 20 and matching with the height of the conductive connector 50.

### Embodiment 3

The present embodiment provides a display device, as shown in FIG. 8, the display device includes a driving unit 200 and an OLED display panel 100, wherein the driving unit 200 provides a driving signal to the OLED display panel 100. The OLED display panel 100 employs the touch OLED display panel described in Embodiment 1 or Embodiment 2 of the present disclosure. Wherein the driving signal includes a display driving signal and a touch driving signal, specifically, the driving unit 200 includes a display driving chip and a touch driving chip, the display driving chip and the touch driving chip are connected to the chip bonding portion on the TFT array substrate respectively. In some specifically embodiment, the display driving chip and the touch driving chip can be integrated in the same chip with the display driving function and the touch driving function.

In summary, the touch OLED display panel and the display device provided in the embodiments of the present disclosure have the advantages of being simple in structure, thin in thickness and having high light transmittance by embedding the touch structure in the OLED display panel.

It should be noted that, in this article, relational terms, such as first and second, and the like, are only used to distinguish one entity or operation from another, not necessarily requiring or implying any actual relationship or order between such entities or operations. Moreover, the terms “comprising,” “including,” or any other variation thereof, are intended to cover a non-exclusive inclusion such that a process, method, article, or apparatus that includes a list of elements includes not only those elements, but also include other elements not expressly listed or also include elements inherent to the process, method, article, or device. Without further limitations, an element limited by the statement “including a . . . ” does not exclude the existence of additional identical elements in the process, method, article, or apparatus that includes the element.

The foregoing descriptions are merely specific implementation manners of the present application. It should be noted that, for those skilled in the art, several improvements and modifications can be made without departing from the principle of the present disclosure, and these improvements and modifications should also be considered as the protection scope of the present application.

What is claimed is:

1. A touch OLED display panel, comprising a TFT array substrate and an package cover plate opposite to each other, and a conductive connector arranged between the TFT array substrate and the package cover plate, wherein the TFT array substrate is provided with a chip bonding portion and a first connection terminal electrically connected to each other, a side of the package cover plate facing the TFT array substrate is provided with a touch electrode layer and a second connection terminal electrically connected to each other, the conductive connector electrically connects the first connection terminal and the second connection terminal to each other.

2. The touch OLED display panel according to claim 1, wherein an organic light emitting structure layer is arranged on the TFT array substrate, a sealant frame is arranged between the TFT array substrate and the package cover plate, wherein the sealant frame surrounds the periphery of the organic light emitting structure layer, the chip bonding portion, the first connection terminal, the second connection terminal and the conductive connector are all located outside the sealant frame, and the touch electrode layer is located inside the sealant frame.

3. The touch OLED display panel according to claim 2, wherein the chip bonding portion and the first connection terminal are arranged on a first side outside the sealant frame, and the second connection terminal is located on the first connection terminal.

4. The touch OLED display panel according to claim 3, wherein a notch is formed on an area of the package cover plate corresponding to the first side, and the second connection terminal is arranged on a projection of both sides of the notch.

5. The touch OLED display panel according to claim 2, wherein the chip bonding portion is arranged on the first side outside the sealant frame, the first connection terminal is arranged on a second side that is different from the first side and outside the sealant frame, the second connection terminal is located on the first connection terminal, and a connection trace between the first connection terminal and the chip bonding portion is arranged at an edge area of the TFT array substrate.

6. The touch OLED display panel according to claim 5, wherein a notch is formed on an area of the package cover plate corresponding to the second side, and the second connection terminal is arranged on a projection of both sides of the notch.

7. The touch OLED display panel according to claim 2, wherein the organic light emitting structure layer comprises an anode layer, a luminescent material layer and a cathode layer arranged on the TFT array substrate sequentially.

8. The touch OLED display panel according to claim 1, wherein the conductive connector is an anisotropic conductive adhesive.

9. The touch OLED display panel according to claim 8, wherein a support member is further arranged at a position adjacent to the conductive connector and between the TFT array substrate and package cover plate.

10. The touch OLED display panel according to claim 1, wherein a support member is further arranged at a position adjacent to the conductive connector and between the TFT array substrate and package cover plate.

11. A display device, comprising a driving unit and a touch OLED display panel, wherein the driving unit provides a driving signal to the touch OLED display panel, and the touch OLED display panel comprises a TFT array substrate and an package cover plate opposite to each other, and a conductive connector arranged between the TFT array substrate and the package cover plate, wherein the TFT array substrate is provided with a chip bonding portion and a first connection terminal electrically connected to each other, a side of the package cover plate facing the TFT array substrate is provided with a touch electrode layer and a second connection terminal electrically connected to each other, the conductive connector electrically connects the first connection terminal and the second connection terminal to each other.

12. The display device according to claim 11, wherein an organic light emitting structure layer is arranged on the TFT array substrate, a sealant frame is arranged between the TFT array substrate and the package cover plate, wherein the sealant frame surrounds the periphery of the organic light emitting structure layer, the chip bonding portion, the first connection terminal, the second connection terminal and the conductive connector are all located outside the sealant frame, and the touch electrode layer is located inside the sealant frame.

13. The display device according to claim 12, wherein the chip bonding portion and the first connection terminal are arranged on a first side outside the sealant frame, and the second connection terminal is located on the first connection terminal.

14. The display device according to claim 13, wherein a notch is formed on an area of the package cover plate corresponding to the first side, and the second connection terminal is arranged on a projection of both sides of the notch.

15. The display device according to claim 12, wherein the chip bonding portion is arranged on the first side outside the sealant frame, the first connection terminal is arranged on a second side that is different from the first side and outside the sealant frame, the second connection terminal is located on the first connection terminal, and a connection trace between the first connection terminal and the chip bonding portion is arranged at an edge area of the TFT array substrate.

16. The display device according to claim 15, wherein a notch is formed on an area of the package cover plate corresponding to the second side, and the second connection terminal is arranged on a projection of both sides of the notch.

17. The display device according to claim 12, wherein the organic light emitting structure layer comprises an anode layer, a luminescent material layer and a cathode layer arranged on the TFT array substrate sequentially.

18. The display device according to claim 1, wherein the conductive connector is an anisotropic conductive adhesive.

19. The display device according to claim 18, wherein a support member is further arranged at a position adjacent to the conductive connector and between the TFT array substrate and package cover plate.

20. The display device according to claim 11, wherein a support member is further arranged at a position adjacent to the conductive connector and between the TFT array substrate and package cover plate.
